(19) United States
(12) Patent Application Publication
(10) Pub. No.: US 2026/0304667 A1
(43) Pub. Date: Oct. 1, 2026

(54) INSERTION/EJECTION MECHANISM FOR A CIRCUIT CARD

(71) Applicant: Nokia Solutions and Networks Oy, Espoo (FI)

(72) Inventor: Michael DiCristoforo, Bow, NH (US)

(73) Assignee: Nokia Solutions and Networks Oy, Espoo (FI)

(21) Appl. No.: 19/095,927

(22) Filed: Mar. 31, 2025

(51) Int. Cl. H05K 7/14

(52) U.S. Cl. CPC H05K 7/1409

(57) ABSTRACT

A mechanism for inserting and ejecting a component (e.g., a circuit card) into and from a housing (e.g., a chassis). The mechanism has (i) at least one pawl rotatably connected at a distal end to the component and having a cam follower and a pin at a proximal end of the pawl and (ii) a lever having at least one cam that engages with the pawl's cam follower. As the lever is rotated from a fully open configuration to a fully closed configuration, the cam rotates within the cam follower first to extend the pin into a receptacle of the housing and then to push the component towards the housing. As the lever is de-rotated from the fully closed configuration to the fully open configuration, the cam de-rotates within the cam follower first to pull the component away from the housing and then to retract the pin from the receptacle.

### BACKGROUND

### Field of the Disclosure

The present disclosure relates to chassis for circuit cards and, more specifically, to mechanisms for inserting and ejecting circuit cards into and from such chassis.

### Description of the Related Art

This section introduces aspects that may help facilitate a better understanding of the disclosure. Accordingly, the statements of this section are to be read in this light and are not to be understood as admissions about what is prior art or what is not prior art.

It is known to house rows of circuit cards in chassis. In some designs, it can be difficult or awkward to insert and/or remove individual circuit cards to and/or from such a chassis.

### SUMMARY

Problems in the prior art are addressed in accordance with the principles of the present disclosure by a new mechanism for inserting and ejecting a circuit card into and from a chassis. Certain embodiments are mechanisms for inserting and ejecting a circuit card into and from a chassis. The mechanism has (i) at least one pawl rotatably connected at a distal end to the circuit card and having a cam follower and a pin at a proximal end of the pawl and (ii) a lever having at least one cam that engages with the pawl's cam follower. As the lever is rotated from a fully open configuration to a fully closed configuration, the cam rotates within the cam follower first to extend the pin into a receptacle of the chassis and then to push the circuit card towards the chassis. As the lever is de-rotated from the fully closed configuration to the fully open configuration, the cam de-rotates within the cam follower first to pull the circuit card away from the chassis and then to retract the pin from the receptacle, thereby enabling the circuit card to be fully removed from the chassis.

### BRIEF DESCRIPTION OF THE DRAWINGS

Embodiments of the disclosure will become more fully apparent from the following detailed description, the appended claims, and the accompanying drawings in which like reference numerals identify similar or identical elements.

FIG. 1 is a perspective view of a chassis with eight, fully inserted, circuit cards;

FIG. 2A is a perspective view of a single circuit card of FIG. 1 with its two (i.e., upper and lower) insertion/ejection mechanisms in their fully open configurations;

FIG. 2B is a perspective view of that same circuit card with its two insertion/ejection mechanisms in their fully closed configurations.

FIG. 3 is a perspective, cutaway view of the chassis of FIG. 1 with the single circuit card of FIG. 2A partially inserted into the chassis with the circuit card's two insertion/ejection mechanisms in their fully open configurations;

FIG. 4A is a side view of the lower insertion/ejection mechanism of FIGS. 2A, 2B, and 3 in its fully open configuration;

FIG. 4B is a side view of that same lower insertion/ejection mechanism in a partially open/partially closed configuration;

FIG. 4C is a side view of that same lower insertion/ejection mechanism 210 in its fully closed configuration;

FIG. 5 is a perspective view of the lever of FIGS. 4A-4C;

FIG. 6 is a perspective view of each pawl of FIGS. 4A-4C; and

FIGS. 7A-7C are side views of the insertion/ejection mechanism in the configurations of FIGS. 4A-4C, respectively, with respect to the chassis of FIG. 1.

### DETAILED DESCRIPTION

Detailed illustrative embodiments of the present disclosure are disclosed herein. However, specific structural and functional details disclosed herein are merely representative for purposes of describing example embodiments of the present disclosure. The present disclosure may be embodied in many alternate forms and should not be construed as limited to only the embodiments set forth herein. Further, the terminology used herein is for the purpose of describing particular embodiments only and is not intended to be limiting of example embodiments of the disclosure.

As used herein, the singular forms “a,” “an,” and “the,” are intended to include the plural forms as well, unless the context clearly indicates otherwise. It further will be understood that the terms “comprises,” “comprising,” “contains,” “containing,” “includes,” and/or “including,” specify the presence of stated features, steps, or components, but do not preclude the presence or addition of one or more other features, steps, or components. It also should be noted that in some alternative implementations, the functions/acts noted may occur out of the order noted in the figures. For example, two figures shown in succession may in fact be executed substantially concurrently or may sometimes be executed in the reverse order, depending upon the functions/acts involved.

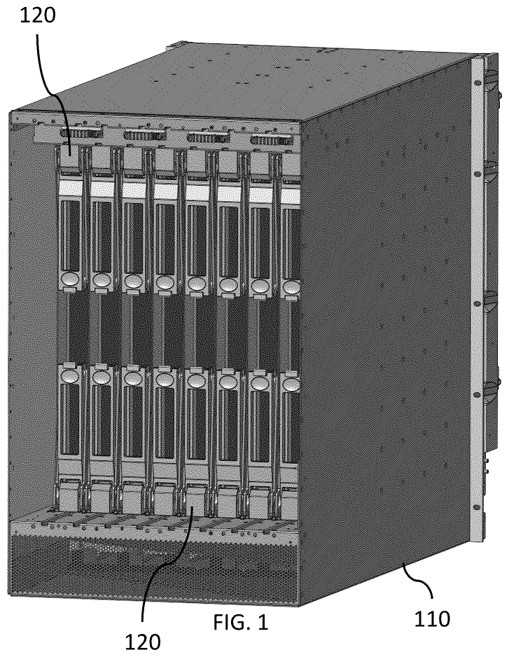

FIG. 1 is a perspective view of a chassis 110 with eight, fully inserted, circuit cards 120.

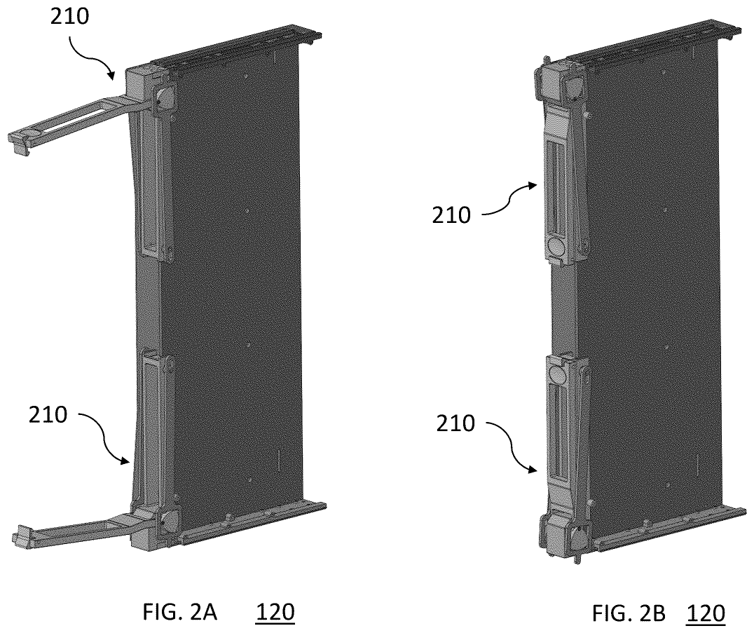

FIG. 2A is a perspective view of a single circuit card 120 of FIG. 1 with its two (i.e., upper and lower) insertion/ejection mechanisms 210 in their fully open configurations, while FIG. 2B is a perspective view of that same circuit card 120 with its two insertion/ejection mechanisms 210 in their fully closed configurations.

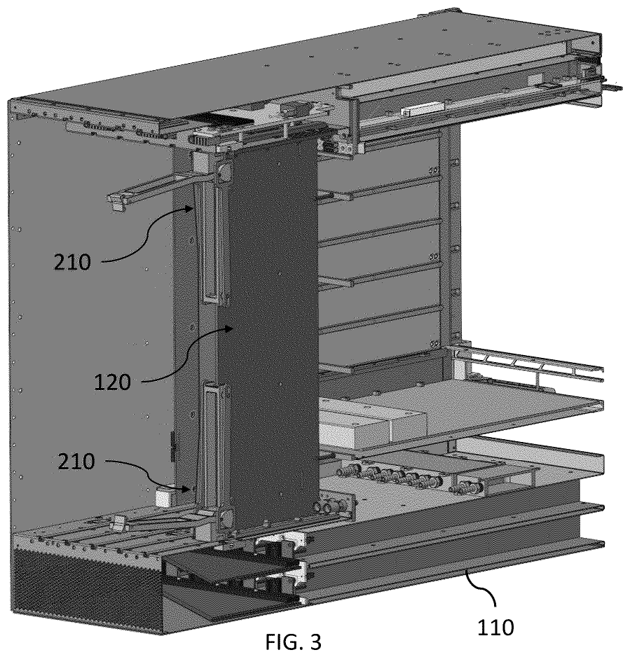

FIG. 3 is a perspective, cutaway view of the chassis 110 of FIG. 1 with the single circuit card 120 of FIG. 2A partially inserted into the chassis 110 with the circuit card's two insertion/ejection mechanisms 210 in their fully open configurations.

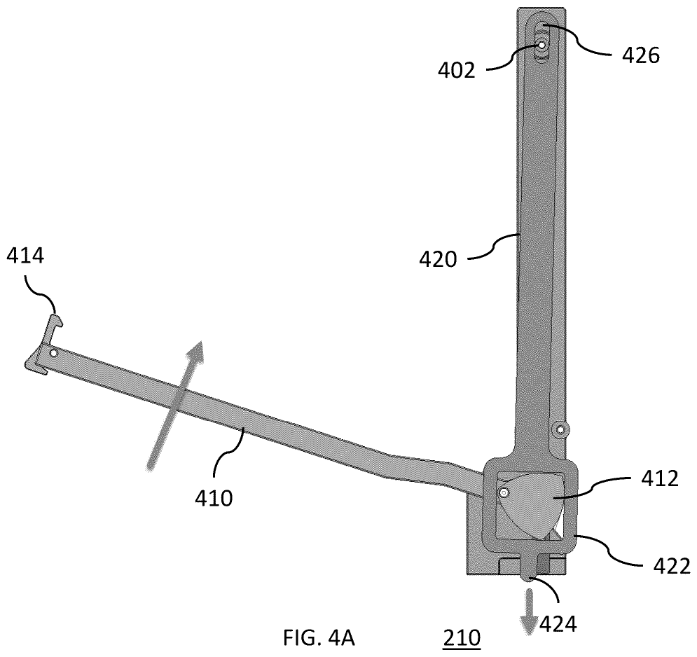

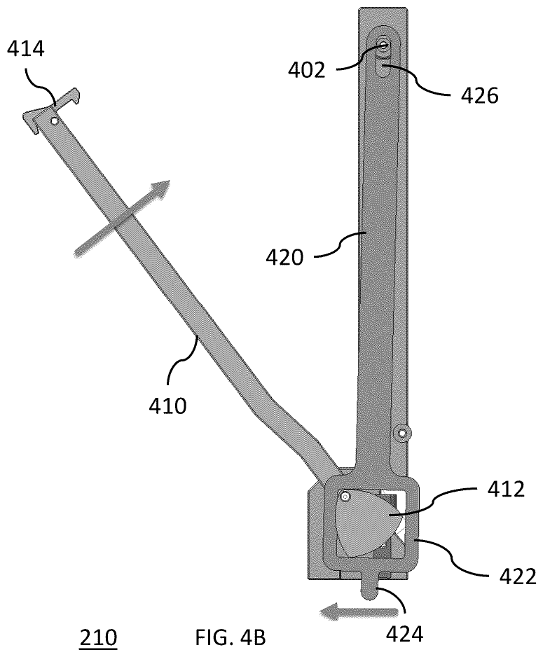

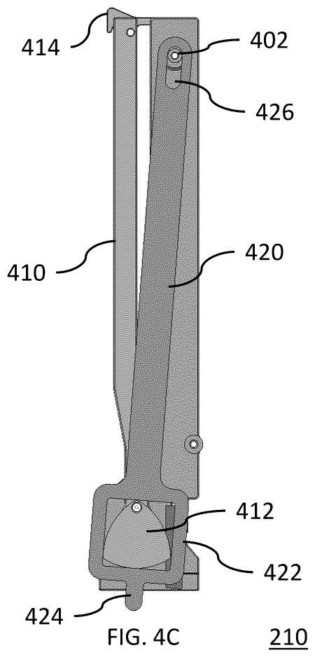

FIG. 4A is a side view of the lower insertion/ejection mechanism 210 of FIGS. 2A, 2B, and 3 in its fully open configuration (as in FIGS. 2A and 3), FIG. 4B is a side view of that same lower insertion/ejection mechanism 210 in a partially open/partially closed configuration, and FIG. 4C is a side view of that same lower insertion/ejection mechanism 210 in its fully closed configuration (as in FIG. 2B). As shown in FIGS. 4A-4C, the insertion/ejection mechanism 210 comprises a lever 410 and two pawls 420 (only one of which is visible in FIGS. 4A-4).

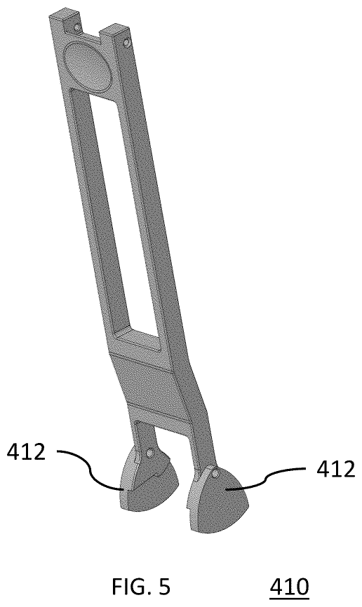

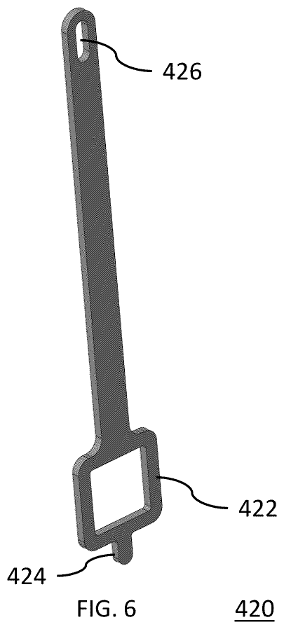

FIG. 5 is a perspective view of the lever 410 of FIGS. 4A-4C, and FIG. 6 is a perspective view of each pawl 420 of FIGS. 4A-4C. As shown in FIGS. 5 and 6, the lever 410 has two opposing cams 412, and each pawl 420 has a cam follower 422 that is designed to engage with one of the lever's cams 412.

In particular, at its proximal end, each pawl 420 has a cam follower 422 having a substantially square opening and a protruding pin 424. At its distal end, each pawl 420 has a slot 426 that pivotally and slidably connects the pawl 420 to a mounting pin 402 that is rigidly connected to rest of the circuit board 120.

At its proximal end, the lever 410 has two substantially, equilaterally triangular cams 412 that are rotatably mounted within and engage with the cam follower openings of the two pawls 420, respectively. At its distal end, the lever 410 has a locking mechanism 414 that is configured to engage with structure on the circuit board 120 to lock the lever 410 into the fully closed configuration of FIG. 4C.

As shown in FIG. 4A, in the fully open configuration, each cam 412 engages with the corresponding cam follower 422 to push the corresponding pawl 420 up (in the view of FIG. 4A) such that the mounting pin 402 is at the bottom of the pawl slot 426. In this configuration, the cam follower pin 424 is at its highest elevation.

As the lever 410 is rotated (clockwise in FIGS. 4A and 4B) from the fully open configuration of FIG. 4A to the partially open/partially closed configuration of FIG. 4B, each cam 412 engages with the corresponding cam follower 422 to pull the corresponding pawl 420 down (in the view of FIGS. 4A and 4B) such that the mounting pin 402 is at the top of the pawl slot 426 in FIG. 4B. In this partially open/partially closed configuration, the cam follower pin 424 is at its lowest elevation.

As the lever 410 is further rotated (clockwise in FIGS. 4B and 4C) from the partially open/partially closed configuration of FIG. 4B to the fully closed configuration of FIG. 4C, each cam 412 engages with the corresponding cam follower 422 to rotate the corresponding pawl 420 clockwise (in FIGS. 4B and 4C) about the mounting pin 402, while keeping the mounting pin 402 is at the top of the pawl slot 426, such that the cam follower pin 424 moves from right to left (in the view of FIGS. 4B and 4C) while substantially maintaining its lowest elevation.

Note that, as the lever 410 is de-rotated (counterclockwise in FIGS. 4C and 4B) from the fully closed configuration of FIG. 4C to the partially open/partially closed configuration of FIG. 4B, each cam 412 engages with the corresponding cam follower 422 to de-rotate the corresponding pawl 420 (counterclockwise in FIGS. 4C and 4B) about the mounting pin 402, while keeping the mounting pin 402 at the top of the pawl slot 426, such that the cam follower pin 424 moves from left to right (in the view of FIGS. 4C and 4B) while again substantially maintaining its lowest elevation.

Similarly, as the lever 410 is further de-rotated (counterclockwise in FIGS. 4B and 4A) from the partially open/partially closed configuration of FIG. 4B to the fully open configuration of FIG. 4A, each cam 412 engages with the corresponding cam follower 422 to push the corresponding pawl 420 up such that, in FIG. 4A, the mounting pin 402 is again at the bottom of the pawl slot 426 and the cam follower pin 424 is again raised to its highest elevation.

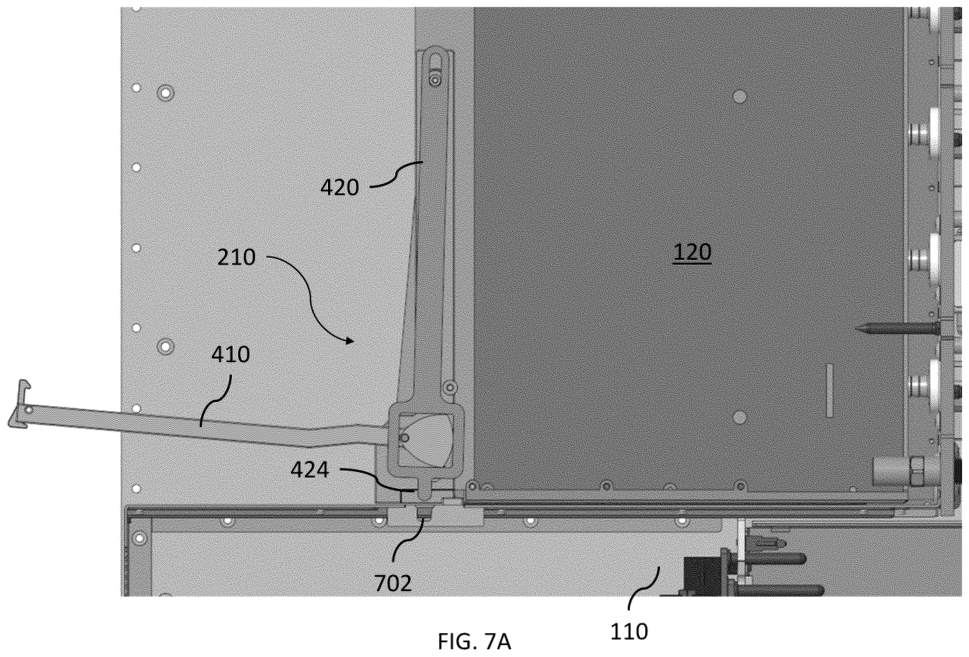

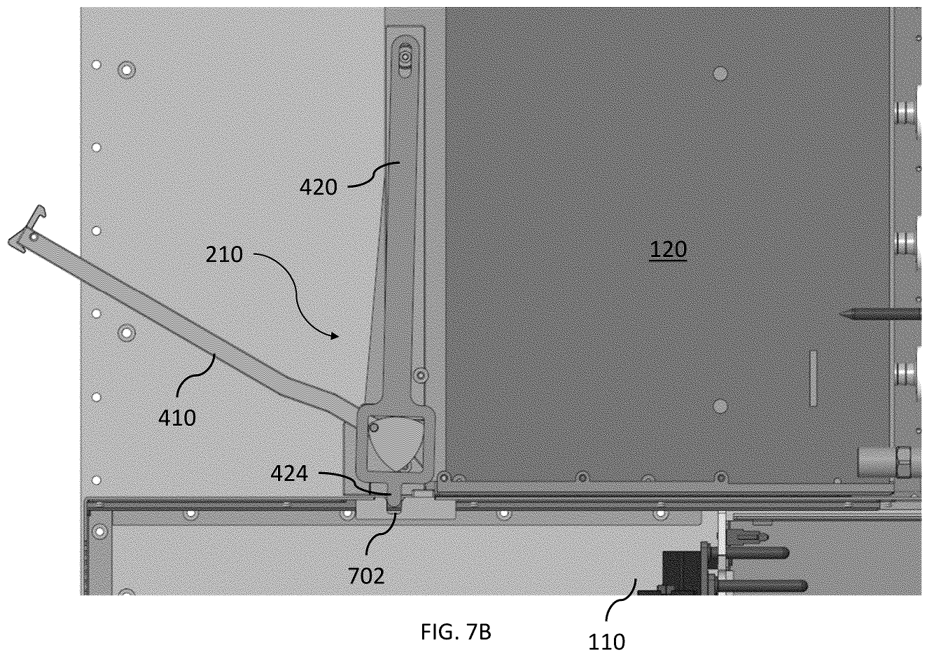

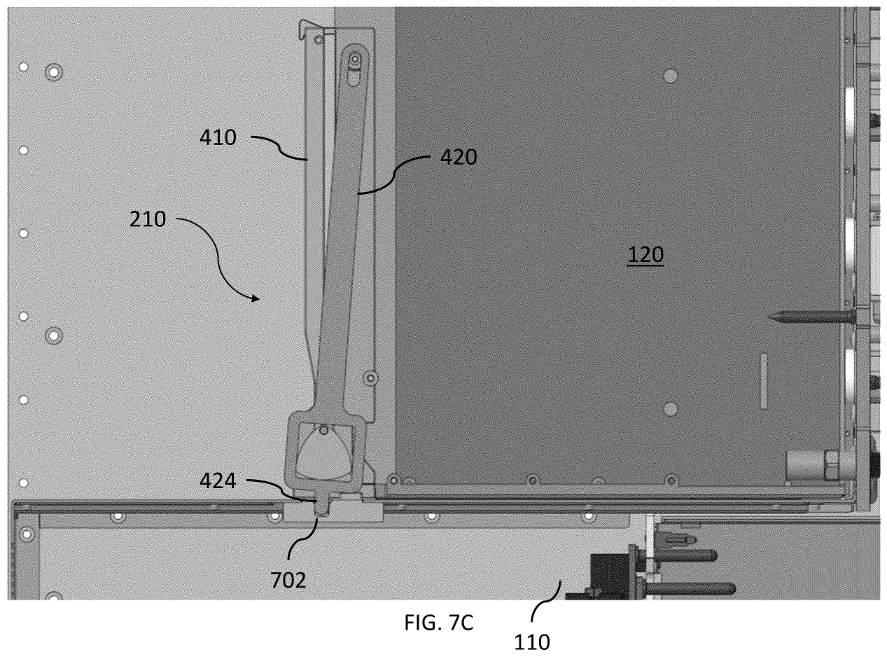

FIGS. 7A-7C are side views of the insertion/ejection mechanism 210 in the configurations of FIGS. 4A-4C, respectively, with respect to the chassis 110 of FIG. 1. In particular, FIG. 7A shows the circuit card 120 almost fully inserted (e.g., by hand) into the chassis 110 with the insertion/ejection mechanism 210 in its fully open configuration with the cam follower pin 424 positioned over a pin receptacle 702 of the chassis 110. FIG. 7B shows the circuit card 120 at the same almost fully inserted position into the chassis 110 with the insertion/ejection mechanism 210 in its partially open/partially closed configuration with the cam follower pin 424 lowered into the pin receptacle 702 of the chassis 110. As the lever 410 is rotated (clockwise in FIGS. 7B and 7C), the cam follower pin 424 moves from left to right (in the view of FIGS. 7B and 7C) and the engagement of the cam follower pin 424 within the chassis's pin receptacle 702 pushes the circuit card 120 to the right into its fully inserted position within the chassis 110, thereby completing the process of inserting the circuit card 120 into the chassis 110.

To eject the circuit card 120 from the chassis, the process is reversed by de-rotating the lever 410 (counterclockwise in FIGS. 7C and 7B) from the fully closed configuration of FIG. 7C to the partially open/partially closed configuration of FIG. 7B, resulting in the cam follower pin 424 moving from right to left (in the view of FIGS. 7C and 7B) and the engagement of the cam follower pin 424 within the chassis's pin receptacle 702 moving the circuit card 120 from right to left, thereby disconnecting the circuit card 120 from the chassis 110. As the lever is continued to be de-rotated (counterclockwise in FIGS. 7B and 7A) from the partially open/partially closed configuration of FIG. 7B to the fully open configuration of FIG. 7A, the cam follower pin 424 is retracted from the pin receptable 702, thereby enabling the circuit card 120 to be fully removed from the chassis 110 (e.g., by hand) and completing the ejection of the circuit card 120 from the chassis 110.

Those skilled in the art will understand that the upper insertion/ejection mechanism 210 of FIGS. 2A-2B has analogous pawl and level components that operate in reciprocal manner in tandem with the lower insertion/ejection mechanism 210 to insert and eject the circuit card 120 into and from the chassis 110. In other words, to properly insert the circuit card 120 into the chassis 110, the levers 410 of both the upper and lower insertion/ejection mechanisms 210 are rotated at the same time from their fully open configurations to their fully closed configurations. Likewise, to properly eject the circuit card 120 from the chassis 110, the levers 410 of both the upper and lower insertion/ejection mechanisms 210 are rotated at the same time from their fully closed configurations to their fully open configurations.

Note that, in the embodiment of FIG. 1, each circuit card 120 has an identical pair of upper and lower insertion/ejection mechanisms 210 for inserting and ejecting that circuit card 120 into and from the chassis 110.

Although each cam has a substantially equilaterally triangular shape and each cam follower opening has a substantially square shape, those skilled in the art will understand that cam and cam follower openings may have different, suitable shapes that achieve the same or equivalent functionality for inserting and ejecting a circuit card into and from a chassis.

Although the disclosure has been described in the context of inserting and ejecting circuit cards into and from chassis, those skilled in the art will understand that the insertion/ejection mechanism of the disclosure may be used to insert and remove other types of components into and from other types of housing.

In certain embodiments, the present disclosure is an apparatus comprising a first mechanism for inserting and ejecting a component into and from a housing. The first mechanism comprises (i) at least one pawl rotatably connected at a distal end to the component and having a cam follower and a pin at a proximal end of the pawl and (ii) a lever having at least one cam that engages with the cam follower. As the lever is rotated from a fully open configuration to a fully closed configuration, the cam rotates within the cam follower first to extend the pin into a receptacle of the housing and then to push the component towards the housing. As the lever is de-rotated from the fully closed configuration to the fully open configuration, the cam de-rotates within the cam follower first to pull the component away from the housing and then to retract the pin from the receptacle.

In at least some of the above embodiments, the component is a circuit card, and the housing is a chassis.

In at least some of the above embodiments, the apparatus is the first mechanism.

In at least some of the above embodiments, the apparatus is the component having the first mechanism.

In at least some of the above embodiments, the apparatus comprises the component having the first mechanism and the housing.

In at least some of the above embodiments, the cam follower has a substantially square opening, and the cam has a substantially triangular shape.

In at least some of the above embodiments, at the fully open configuration, the lever is substantially at a right angle with respect to the pawl and, at the fully closed configuration, the lever is substantially at a zero angle with respect to the pawl.

In at least some of the above embodiments, as the lever is rotated from the fully open configuration to a partially open/partially closed configuration, the cam rotates within the cam follower to extend the pin into the receptacle. As the lever is rotated from the partially open/partially closed configuration to the fully closed configuration, the cam rotates within the cam follower to push the component towards the housing. As the lever is de-rotated from the fully closed configuration about the partially open/partially closed configuration, the cam de-rotates within the cam follower to pull the component away from the housing. As the lever is de-rotated from about the partially open/partially closed configuration to the fully open configuration, the cam de-rotates within the cam follower to retract the pin from the receptacle.

In at least some of the above embodiments, at the fully open configuration, the pin is not within the receptable such that the component is free to move with respect to the housing. At the fully closed configuration, the pin is within the receptable such that the component is not free to move with respect to the housing.

In at least some of the above embodiments, the component has a second assembly that is analogous to the first assembly, where one of the first and second assemblies is mounted at a top of the component and the other is mounted at a bottom of the component.

In at least some of the above embodiments, the first mechanism comprises (i) two pawls rotatably connected at their distal ends to the component, each pawl having a cam follower and a pin at a proximal end of the pawl and (ii) the lever comprises two cams that respectively engage with the cam followers of the two pawls.

Unless explicitly stated otherwise, each numerical value and range should be interpreted as being approximate as if the word “about” or “approximately” preceded the value or range.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence. Likewise, additional steps may be included in such methods, and certain steps may be omitted or combined, in methods consistent with various embodiments of the disclosure.

Reference herein to “one embodiment” or “an embodiment” means that a particular feature, structure, or characteristic described in connection with the embodiment can be included in at least one embodiment of the disclosure. The appearances of the phrase “in one embodiment” in various places in the specification are not necessarily all referring to the same embodiment, nor are separate or alternative embodiments necessarily mutually exclusive of other embodiments. The same applies to the term “implementation.”

Unless otherwise specified herein, the use of the ordinal adjectives “first,” “second,” “third,” etc., to refer to an object of a plurality of like objects merely indicates that different instances of such like objects are being referred to, and is not intended to imply that the like objects so referred-to have to be in a corresponding order or sequence, either temporally, spatially, in ranking, or in any other manner.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements. The same type of distinction applies to the use of terms “attached” and “directly attached,” as applied to a description of a physical structure.

As used herein in reference to an element and a standard, the terms “compatible” and “conform” mean that the element communicates with other elements in a manner wholly or partially specified by the standard and would be recognized by other elements as sufficiently capable of communicating with the other elements in the manner specified by the standard. A compatible or conforming element does not need to operate internally in a manner specified by the standard.

The described embodiments are to be considered in all respects as only illustrative and not restrictive. In particular, the scope of the disclosure is indicated by the appended claims rather than by the description and figures herein. All changes that come within the meaning and range of equivalency of the claims are to be embraced within their scope.

In this specification including any claims, the term “each” may be used to refer to one or more specified characteristics of a plurality of previously recited elements or steps. When used with the open-ended term “comprising,” the recitation of the term “each” does not exclude additional, unrecited elements or steps. Thus, it will be understood that an apparatus may have additional, unrecited elements and a method may have additional, unrecited steps, where the additional, unrecited elements or steps do not have the one or more specified characteristics.

As used herein, “at least one of the following: <a list of two or more elements>” and “at least one of <a list of two or more elements>” and similar wording, where the list of two or more elements are joined by “and” or “or”, mean at least any one of the elements, or at least any two or more of the elements, or at least all the elements. For example, the phrases “at least one of A and B” and “at least one of A or B” are both to be interpreted to have the same meaning, encompassing the following three possibilities: 1—only A; 2—only B; 3—both A and B.

All documents mentioned herein are hereby incorporated by reference in their entirety or alternatively to provide the disclosure for which they were specifically relied upon.

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

While preferred embodiments of the disclosure have been shown and described herein, it will be obvious to those skilled in the art that such embodiments are provided by way of example only. Numerous variations, changes, and substitutions will now occur to those skilled in the art without departing from the disclosure. It should be understood that various alternatives to the embodiments of the disclosure described herein may be employed in practicing the technology of the disclosure. It is intended that the following claims define the scope of the invention and that methods and structures within the scope of these claims and their equivalents be covered thereby.

What is claimed is:

1. An apparatus comprising a first mechanism for inserting and ejecting a component into and from a housing, the first mechanism comprising:
at least one pawl rotatably connected at a distal end to the component and having a cam follower and a pin at a proximal end of the pawl; and
a lever having at least one cam that engages with the cam follower, wherein:
as the lever is rotated from a fully open configuration to a fully closed configuration, the cam rotates within the cam follower first to extend the pin into a receptacle of the housing and then to push the component towards the housing; and
as the lever is de-rotated from the fully closed configuration to the fully open configuration, the cam de-rotates within the cam follower first to pull the component away from the housing and then to retract the pin from the receptacle.

2. The apparatus of claim 1, wherein:
the component is a circuit card; and
the housing is a chassis.

3. The apparatus of claim 1, wherein the apparatus is the first mechanism.

4. The apparatus of claim 1, wherein the apparatus is the component having the first mechanism.

5. The apparatus of claim 1, wherein the apparatus comprises the component having the first mechanism and the housing.

6. The apparatus of claim 1, wherein:
the cam follower has a substantially square opening; and
the cam has a substantially triangular shape.

7. The apparatus of claim 1, wherein:
at the fully open configuration, the lever is substantially at a right angle with respect to the pawl; and
at the fully closed configuration, the lever is substantially at a zero angle with respect to the pawl.

8. The apparatus of claim 1, wherein:
as the lever is rotated from the fully open configuration to a partially open/partially closed configuration, the cam rotates within the cam follower to extend the pin into the receptacle;
as the lever is rotated from the partially open/partially closed configuration to the fully closed configuration, the cam rotates within the cam follower to push the component towards the housing;
as the lever is de-rotated from the fully closed configuration about the partially open / partially closed configuration, the cam de-rotates within the cam follower to pull the component away from the housing; and
as the lever is de-rotated from about the partially open/partially closed configuration to the fully open configuration, the cam de-rotates within the cam follower to retract the pin from the receptacle.

9. The apparatus of claim 1, wherein:
at the fully open configuration, the pin is not within the receptable such that the component is free to move with respect to the housing; and
at the fully closed configuration, the pin is within the receptable such that the component is not free to move with respect to the housing.

10. The apparatus of claim 1, wherein the component has a second assembly that is analogous to the first assembly, where one of the first and second assemblies is mounted at a top of the component and the other is mounted at a bottom of the component.

11. The apparatus of claim 1, wherein the first mechanism comprises:
two pawls rotatably connected at their distal ends to the component, each pawl having a cam follower and a pin at a proximal end of the pawl; and
the lever comprises two cams that respectively engage with the cam followers of the two pawls.

12. A method for inserting and ejecting a component into and from a housing using a first mechanism comprising (i) at least one pawl rotatably connected at a distal end to the component and having a cam follower and a pin at a proximal end of the pawl and (ii) a lever having at least one cam that engages with the cam follower, the method comprising:
rotating the lever from a fully open configuration to a fully closed configuration to rotate the cam within the cam follower first to extend the pin into a receptacle of the housing and then to push the component towards the housing; and
de-rotating the lever from the fully closed configuration to the fully open configuration to de-rotate the cam within the cam follower first to pull the component away from the housing and then to retract the pin from the receptacle.

13. The method of claim 12, wherein:
the component is a circuit card; and
the housing is a chassis.

14. The method of claim 12, wherein:
the cam follower has a substantially square opening; and
the cam has a substantially triangular shape.

15. The method of claim 12, wherein:
at the fully open configuration, the lever is substantially at a right angle with respect to the pawl; and
at the fully closed configuration, the lever is substantially at a zero angle with respect to the pawl.

16. The method of claim 12, wherein:
as the lever is rotated from the fully open configuration to a partially open/partially closed configuration, the cam rotates within the cam follower to extend the pin into the receptacle;
as the lever is rotated from the partially open/partially closed configuration to the fully closed configuration, the cam rotates within the cam follower to push the component towards the housing;
as the lever is de-rotated from the fully closed configuration about the partially open/partially closed configuration, the cam de-rotates within the cam follower to pull the component away from the housing; and
as the lever is de-rotated from about the partially open/partially closed configuration to the fully open configuration, the cam de-rotates within the cam follower to retract the pin from the receptacle.

17. The method of claim 12, wherein:
at the fully open configuration, the pin is not within the receptable such that the component is free to move with respect to the housing; and
at the fully closed configuration, the pin is within the receptable such that the component is not free to move with respect to the housing.

18. The method of claim 12, wherein the component has a second assembly that is analogous to the first assembly, where one of the first and second assemblies is mounted at a top of the component and the other is mounted at a bottom of the component.

19. The method of claim 12, wherein the first mechanism comprises:
two pawls rotatably connected at their distal ends to the component, each pawl having a cam follower and a pin at a proximal end of the pawl; and
the lever comprises two cams that respectively engage with the cam followers of the two pawls.
